(19) United States
(12) Patent Application Publication
(10) Pub. No.: US 2004/0175500 A1
(43) Pub. Date: Sep. 9, 2004

(54) Method for forming transparent conductive film, transparent conductive film, glass substrate having the same and photoelectric transduction unit including the glass substrate

(76) Inventors: Akira Fujisawa, Osaka-shi (JP); Koichiro Kiyohara, Osaka-shi (JP); Masahiro Hirata, Osaka-shi (JP); Kiyotaka Ichiki, Osaka-shi (JP); Toru Sawada, Uji-shi (JP)

Correspondence Address: MERCHANT & GOULD PC, P.O. BOX 2903, MINNEAPOLIS, MN, 55402-0903, US

(21) Appl. No.: 10/484,065

(22) PCT Filed: Jan. 27, 2003
(86) PCT No.: PCT/JP03/00707

(30) Foreign Application Priority Data
Jan. 28, 2002 (JP) 2002-18365

(51) Int. Cl. B32B 17/06; C23C 16/00

(52) U.S. Cl. 427/255.28; 136/243; 428/432; 427/162

(57) ABSTRACT

The present invention presents a method for forming a transparent conductive film whose principal component is tin oxide by so-called CVD on a glass ribbon, preventing the generation of giant crystal grains in the tin oxide, while ensuring that the concentration of carbon is low, or in other words, the absorption coefficient at 400 to 550 nm wavelength is low. In accordance with the invention, the method for forming a transparent conductive film whose principal component is tin oxide by CVD on a glass ribbon includes forming the transparent conductive film at a film deposition speed of 3000 to 7000 nm/min using a raw material gas including 0.5 to 2.0 mol % of an organic tin compound.

### TECHNICAL FIELD

The present invention relates to methods for forming transparent conductive films that are used for photoelectric conversion devices, such as solar cells. Moreover, the present invention relates to glass substrates provided with a transparent conductive film formed with those methods, as well as photoelectric conversion devices using the same.

### BACKGROUND ART

Many types of thin-film photoelectric conversion devices have been researched and developed, and in the most common configuration, a transparent conductive film whose principal component is tin oxide, a thin-film silicon layer serving as the photoelectric conversion layer, and a rear electrode made of aluminum are formed in that order on a transparent substrate, such as a glass sheet or the like. In this configuration, a transparent conductive film is desired that has a high transmittance of visible light, in order to guide more light to the photoelectric conversion layer, and that has a high conductance (low resistance), in order to keep the internal resistance of the solar cell low.

As the transparent conductive film, films whose principal component is tin oxide doped with fluorine are currently mainstream. Such films have better chemical stability, such as plasma resistance, than films of indium oxide doped with tin (ITO), and are also superior with regard to the fact that they suffer little degradation during the film deposition of the photoelectric conversion layer (thin-film silicon layer) by plasma CVD (chemical vapor deposition). Doping with fluorine reduces the resistance, but in order to function properly as electrodes, a certain thickness is necessary. Consequently, transparent electrode films are preferable in which the absorptivity per unit thickness, that is, the absorption coefficient is as small as possible.

A transparent electrode film provided with these preferable properties has been disclosed in JP 2001-35262A. This publication discloses, in a process of manufacturing a glass sheet by the float process, a method for depositing a transparent electrode film by CVD taking organic tin such as dimethyltin dichloride as the raw material in a bath that is filled with a non-oxidizing atmosphere of nitrogen and hydrogen, and molten tin.

Moreover, JP 2000-313960A discloses a CVD process in which nitrogen is taken as the carrier gas and tin tetrachloride, water vapor and hydrogen bromide are applied to the surface of a glass sheet that has been heated to about 500° C.

However, in the method for manufacturing a transparent conductive film according to JP 2001-35262A, consideration is given to the concentration of fluorine and carbon, and efforts are made to keep their concentration within a predetermined range in order to reduce the absorption coefficient. When the concentration of fluorine is too large, then there is also absorption in the visible light region, so that considering only the absorption coefficient of the transparent conductive film, it would be ideal to include no fluorine at all. However, fluorine is a functional component that reduces the resistance of the transparent conductive film, so that a certain amount needs to be included. On the other hand, carbon inevitably remains in the transparent conductive film since it is included in the raw material, and when its content becomes high, then the absorption at wavelengths of 400 to 500 nm becomes large, and the absorption coefficient increases. Consequently, for the transparent conductive film, it would be ideal to contain a small amount of fluorine and contain almost no carbon.

In JP 2000-313960A, tin tetrachloride is used as the tin raw material, and the other raw materials include no organic substances, so that it seems that the transparent conductive film formed with the method of this publication contains no carbon. Therefore, it can be deduced that the absorption coefficient of this transparent conductive film is sufficiently low. Moreover, as stated in this publication, inorganic tin raw materials such as tin tetrachloride are highly reactive, so that the film deposition speed can be maintained even when the temperature of the reaction system and in particular the surface temperature of the glass sheet is relatively low. That is to say, if an inorganic gas raw material is used, the heating of the glass substrate can be kept at a low level while maintaining the film deposition speed, which means that as a result, there is the effect that the film to excessive heating can be prevented. Thus, it seems that if an inorganic tin raw material is used in the CVD process, then a transparent conductive film whose absorption coefficient and deposition costs are low can be easily obtained.

Now, when an inorganic tin raw material is used in a high-temperature reaction system, defects may be formed in the transparent conductive film. For example, in some apparatuses for manufacturing glass sheets by the float process shown in FIG. 1, raw material gas including tin raw material is blown from coaters 16 in a bath 12 (referred to as “shaping bath” in the following) filled with molten tin 15 that is provided to shape molten glass that has been discharged from a glass melting furnace 11 into a glass ribbon 10 of adequate thickness, and the heat of the glass ribbon is utilized to thermally decompose the raw material gas and deposit the transparent conductive film (in the following this film deposition method is referred to as “online CVD”).

In online CVD, a thermal decomposition reaction of the tin raw material advances at the surface of the glass ribbon, which has a temperature from the molten state to near the glass transition temperature (roughly 750 to 560° C.). This thermal decomposition reaction advances by utilizing the heat of the glass ribbon, so that if inorganic tin raw material is used, the thermal decomposition reaction occurs at an early stage, and the crystal growth of the tin oxide advances locally. As a result, giant crystal grains of tin oxide will be deposited at the surface of the transparent conductive film. Incidentally, rather than being completely flat, it is preferable that there is a roughness of a fraction of the wavelength of visible light in the surface of the transparent conductive film. By forming such a roughness in the surface of the transparent conductive film, transmitted light is scattered at the border surface of the transparent conductive film and the photoelectric conversion layer, and a so-called light-confining effect can be attained, in which the optical path length in the photoelectric conversion layer becomes long. Or, the photoelectric conversion layer is formed complementarily to the surface roughness in the transparent conductive film, and the so-called anchor effect works, which has the advantage of increasing their bonding strength. However on the other hand, if giant crystal grains are formed in the surface of the transparent conductive film, then it becomes difficult to form the photoelectric conversion layer uniformly, and moreover, the giant crystal grains may penetrate the photoelectric conversion layer and reach the rear electrodes, causing a short circuit in the photoelectric conversion device. Consequently, in online CVD, in order to use inorganic tin raw material, it is necessary to employ some means to ensure that no giant crystal grains are formed in the transparent conductive film surface.

As such a preventive means, it is conceivable to carry out the film deposition at a location where the temperature of the glass ribbon is lower, such as in the annealing furnace 13, or to set a lower concentration of the raw material gas, but if these means are employed, thermal relaxation after the film deposition becomes difficult, because the film deposition takes place after the glass has hardened, so that the bonding strength of the transparent conductive film may decrease or it may be necessary to slow down the line speed of the glass ribbon in order to deposit the transparent conductive film uniformly, which means that this approach is not necessarily advantageous in an actual industrial setting. Therefore, conventionally these problems are solved by using an organic tin raw material with relatively low reactivity, and as the flip-side of this, carbon remained in the transparent conductive film.

### DISCLOSURE OF THE INVENTION

The present invention was conceived by focusing on these problems. It is an object of the present invention to present a method for forming a transparent conductive film whose principal component is tin oxide by CVD on a glass ribbon, preventing the generation of giant crystal grains in the tin oxide, while ensuring that the concentration of carbon is low, or in other words, the absorption coefficient at 400 to 550 nm wavelength is low. It is another object of the present invention to present a photoelectric conversion device without defects, such as short circuits, and which can display a high photoelectric conversion efficiency, due to using a glass substrate provided with this transparent conductive film.

According to the present invention, the method for forming a transparent conductive film whose principal component is tin oxide by CVD on a glass ribbon comprises film deposition at a film deposition speed of 3000 to 7000 nm/min using a raw material gas including 0.5 to 2.0 mol % of an organic tin compound.

According to another aspect of the present invention, a transparent conductive film formed by the method of the present invention is provided, wherein an absorption coefficient at 400 to 550 nm wavelength is not greater than 0.40×10³ cm⁻¹, and a ratio of the number of carbon atoms to the number of tin atoms is smaller than 4×10⁻³. The present invention further presents a glass substrate on whose surface such a transparent conductive film is formed, and a photoelectric conversion device comprising this glass substrate.

### BRIEF DESCRIPTION OF THE DRAWING

FIG. 1 is a schematic diagram showing an apparatus used for online CVD.

### EMBODIMENTS OF THE INVENTION

The present invention is based on the premise that for the formation of transparent conductive thin films whose principal component is tin oxide, by online CVD, an organic tin compound is used as the tin raw material, and relates to a film deposition method in which the amount of carbon remaining in the transparent conductive film is reduced. As a result of detailed studies of the film deposition conditions when using organic tin raw materials, the inventors have focused on the relation between the concentration of the tin raw material in the raw material gas and the film deposition speed, and have found that within a certain range, the concentration of carbon in the transparent conductive film is much lower than in the related art. More specifically, this is the case if the concentration of organic tin compounds in the raw material gas is 0.5 to 2.0 mol % and the film deposition speed is 3000 to 7000 nm/min, preferably 3000 to 5500 nm/min.

It should be noted that throughout this specification, “principal component” is used in its prevalent meaning, namely a component whose weight content is at least 50 wt %.

The main factors affecting the film deposition speed of the transparent conductive film are the concentration of the tin material and the temperature of the glass ribbon. Other factors include for example the type and concentration of oxidation raw material, such as oxygen, ozone, water vapor or the like, as well as the presence of reaction inhibitors such as hydrogen bromide, but these are not the main factors. The relation between the film deposition speed on the one hand and the concentration of the tin temperature of the glass ribbon become higher, the film deposition speed becomes higher as well, whereas when the concentration of the tin raw material and the temperature of the glass ribbon become lower, then the film deposition speed becomes lower as well. The film deposition speed in online CVD must correspond to the line speed of the glass ribbon, that is, the speed at which the glass ribbon is pulled from the annealing furnace 13, and the film deposition conditions that are set in consideration of this line speed are in the above-noted range.

At an organic tin compound concentration of less than 0.5 mol %, the film deposition speed is less than 500 nm/min, even if the temperature of the glass ribbon is 750° C., and the film deposition speed cannot keep up with the line speed of a glass ribbon with a thickness of 5 mm or less in actual industrial processes, so that there is the problem that a transparent conductive film of the desired thickness cannot be formed. On the other hand, if the concentration exceeds 2.0 mol %, the carbon concentration in the transparent conductive film becomes high, and the film will be like a conventional transparent conductive film.

Particularly preferable as the organic tin compound are dimethyltin dichloride or monobutyltin trichloride. These may be used alone or in combination. Moreover, if 70% or more of at least one selected from dimethyltin dichloride or monobutyltin trichloride is contained, then it can be used preferably as the organic tin compound of the present invention. The reactivity of dimethyltin dichloride and monobutyltin trichloride in the film deposition temperature range for online CVD is not very high, so that by using them, a uniform thin film can be formed over a large surface area. Moreover, they have the advantage that they are easy to obtain and inexpensive, and compared to other organic tin raw materials, have low volatility and are easy to store.

If dimethyltin dichloride is used, it is furthermore preferable to set the concentration to 1.0 to 2.0 mol % and the film deposition speed to 4000 to 6000 nm/min. On the other hand, if monobutyltin trichloride is used, it is preferable to set the concentration to 1.5 to 2.0 mol % and the film deposition speed to 4000 to 6000 nm/min.

In the transparent conductive film formed with this film deposition method, the ratio of the number of carbon atoms to the number of tin atoms (C/Sn) is less than 4×10⁻³, and as a result, the absorption coefficient at wavelength of 400 to 550 nm is not greater than 0.40×10³ cm⁻¹. Moreover, with these preferable film deposition conditions, the ratio of the number of carbon atoms to the number of tin atoms can be reliably decreased to 3×10⁻³ or less, and the absorption coefficient at wavelength of 400 to 550 nm can be reliably decreased to 0.30×10³ cm⁻¹ or less. Here, the absorption coefficient is the coefficient k cm⁻¹ in the equation I=I₀·e^{-kd}, wherein I₀ is the intensity of light that is incident on the thin film and I is the intensity of light that has advanced for a distance of d cm in the thin film direction.

In online CVD, because the inside of the shaping bath is filled with non-oxidizing gas such as nitrogen and hydrogen, the above-noted tin raw materials undergo a thermal decomposition reaction with the oxidation raw material included in the raw material gas. Examples of the oxidation raw material are oxygen, ozone, water vapor and dry air. The oxidation raw material fulfills the function of lowering the carbon concentration in the transparent conductive film, so that it is preferable that it is contained at 10 mol %, more preferably 15 mol % or more in the raw material gas.

Moreover, in order to reduce the sheet resistance of the transparent conductive film, it is desirable to add a fluorine raw material or an antimony raw material to the raw material gas. Examples of fluorine raw materials are hydrogen fluoride, trifluoroacetic acid, bromotrifluoromethane, chlorodifluoromethane and the like. Examples of antimony raw materials are antimony pentachloride and antimony trichloride. It is preferable that the concentration of the fluorine raw material is 0.1 to 1.0 mol %. A suitable carrier gas for transporting these raw materials to the surface of the glass ribbon is nitrogen. Nitrogen is a component that is also present in the gas atmosphere inside the shaping bath, so that it does not affect the properties of the gas atmosphere if it leaks from the coaters.

The fluorine concentration in the transparent conductive film is preferably not greater than 0.1 wt %, more preferably not greater than 0.08 wt %. If the fluorine concentration is too high, the absorption coefficient of the transparent conductive film becomes too large. On the other hand, the fluorine concentration in the transparent conductive film is preferably at least 0.03 wt %, more preferably at least 0.05 wt %. If the fluorine concentration is too low, the specific resistance of the conductive film becomes too large.

If a large amount of alkali components is contained in the glass ribbon, then it is better to provide an undercoating layer before depositing thermally diffuse into the transparent conductive film during the film deposition stage, and diffuse over time even after the film deposition. This diffusion of alkali components reduces the conductivity of the transparent conductive film. In order to address this, with the purpose of preventing the diffusion of alkali components, it is preferable to dispose an undercoating film between the glass ribbon and the transparent conductive film. As the undercoating film, a film is preferable whose principal component is an oxide of at least one metal chosen from the group consisting of silicon, aluminum, tin, titanium and zirconium. Particularly preferable is a film whose principal component is silica (SiO₂) or aluminum oxide. The thickness of the undercoating film is preferably 5 to 100 nm. To function as an undercoating film, a thickness of 5 nm is necessary, whereas in excess of 100 nm, the decrease of visible light transmittance becomes noticeable.

The undercoating film is not limited to a single layer, but may consist of multiple layers. In the case of multiple layers, a preferable configuration has a first undercoating layer whose principal component is for example tin oxide formed on the glass ribbon side, and a second undercoating layer whose principal component is silica. It should be noted that also in the case of multiple layers, it is preferable that the total thickness of the undercoating film is not greater than 100 nm.

The undercoating film is formed by online CVD in the same manner as the transparent conductive film. In the case of an undercoating film whose principal component is silica, it is possible to use monosilane, disilane, trisilane, monochlorosilane, dichlorosilane, 1,2-dimethylsilane, 1,1,2-trimethyldisilane, 1,1,2,2,-tetramethyldisilane, tetramethylorthosilicate, or tetraethylortho-silicate for example as the silicon raw material. Suitable examples of the oxidation raw material for this case include oxygen, water vapor, dry air, nitrogen dioxide, and ozone. In the case of an undercoating film whose principal component is aluminum oxide, it is possible to use trimethylaluminum, aluminum triisopropoxide, diethylaluminum chloride, aluminum acetylacetonate or aluminum chloride for example as the aluminum raw material. Examples of suitable oxidation raw materials for this case include oxygen, water vapor and dry air.

The transparent conductive film may also include silicon, aluminum, zinc, copper, indium, bismuth, gallium, boron, vanadium, manganese, or zirconium. However, it is preferable that the concentration of these trace components other than fluorine is not greater than 0.02 wt %. However, since chlorine is included in form of the organic zinc compound as noted above, its concentration in the transparent conductive film becomes relatively high. For this reason, the concentration of chlorine should be not greater than 0.15 wt %, or preferably not greater than 0.10 wt %.

The sheet resistance of the conductive film is preferably 5 to 40 Ω/□ (square), and more preferably not greater than 30 Ω/□. In consideration of this preferable region of sheet resistance, a preferable film thickness of the transparent conductive film is 300 to 1200 nm, and even more preferably 400 to 1000 nm.

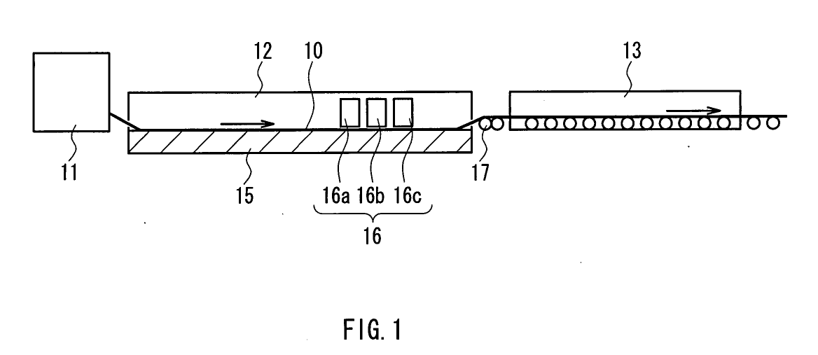

The online CVD process can be implemented using the apparatus shown in FIG. 1. The apparatus shown in FIG. 1 is provided with three coaters 16a, 16b and 16c as the coaters 16, but the number of coaters is not limited to this. A glass ribbon 10 whose top face (that is, the face opposite from the bottom face, which contacts the molten tin 5) is provided with a film made of one or a plurality of layers made from the raw material supplied by the coaters 16 is lifted by a roll 17 to an annealing furnace 13, and after annealing, is cut further downstream to a predetermined shape.

The glass substrate provided with this transparent conductive film can be utilized for photoelectric conversion devices, such as solar cells. The photoelectric conversion devices have at least one photoelectric conversion unit and a rear electrode formed in that order on the transparent conductive film. In the photoelectric conversion devices, the glass substrate side is used as the side on which light is incident.

The photoelectric conversion unit may include a single layer, or it may include multiple layers. Examples of suitable photoelectric conversion units include units in which an amorphous silicon thin film or a crystalline silicon thin film serves as the photoelectric conversion layer (in the following, such units are referred to by indicating the type of the photoelectric conversion layer, such as “amorphous silicon thin-film photoelectric conversion units” and “crystalline silicon thin-film photoelectric conversion units”).

Amorphous silicon thin-film photoelectric conversion units are formed by depositing p-i-n semiconductor layers in that order by plasma CVD. More specifically, a p-type microcrystalline silicon layer doped with at least 0.01 atom % of boron impurities determining conductivity, an intrinsic amorphous silicon layer serving as the photoelectric conversion layer, and an n-type microcrystalline silicon layer doped with at least 0.01% of phosphorus impurities determining conductivity are deposited in that order. However, there is no limitation to these layers, and it is also possible to take for example aluminum as the impurity atoms in the p-type microcrystalline silicon layer, or to use an amorphous silicon layer as the p-type layer. It is also possible to use amorphous or microcrystalline silicon carbide, or an alloy such as silicon-germanium as the p-type layer.

It should be noted that the film thickness of the conductive (p- and n-type) microcrystalline silicon layers is preferably 3 to 100 nm, and more preferably 5 to 50 nm.

It is preferable that the intrinsic amorphous silicon layer is deposited by plasma CVD at not more than 450° C. This layer is formed as a thin film of a substantially intrinsic semiconductor, in which the density of the conductivity-determining impurity atoms is not greater than 1×10¹⁸ cm⁻³. It is preferable that the film thickness of the intrinsic amorphous silicon layer is 0.05 to 0.5 μm. However, in amorphous silicon thin-film photoelectric conversion units, it is also possible to use alloy materials, such as an amorphous silicon carbide layer (for example an amorphous silicon carbide layer made of amorphous silicon containing not more than 10 atom % of carbon) or an amorphous silicon-germanium layer (for example an amorphous silicon-germanium layer made of amorphous silicon containing not more than 30 atom % of germanium), instead of the intrinsic amorphous silicon layer.

Like amorphous silicon thin-film photoelectric conversion units, also crystalline silicon thin-film photoelectric conversion units are made by depositing, by plasma CVD, p-i-n semiconductor layers in that order.

For the rear electrode, it is preferable to form at least one metal layer made of at least one metal selected from aluminum, silver, gold, copper, platinum and chromium by sputtering or vapor deposition. It is also possible to dispose a conductive oxide such as ITO, tin oxide, zinc oxide or the like between the photoelectric conversion units and the metal electrode.

It is preferable that this photoelectric conversion device includes crystalline silicon thin-film photoelectric conversion units. By including such units, the open-circuit voltage that is generated is lower and the generated short-circuit current density is higher than with amorphous silicon thin-film photoelectric conversion units, so that the optical transmittance of the transparent conductive film contributes more to the photoelectric conversion efficiency than its sheet resistance.

### WORKING EXAMPLES

The following is a more detailed description of the present invention with reference to working examples.

First, the following is an explanation of a method for measuring/calculating the absorption coefficient of the transparent conductive film, the component concentrations of carbon and fluorine etc. in the transparent conductive film, and the ratio between the number of tin atoms and the number of carbon atoms in the transparent conductive film.

Absorption Coefficient of the Transparent Conductive Film

Methylene iodide with a refractive index of 1.79 was applied onto the transparent conductive film formed on an undercoating thin film, and a cover glass (#7059 by Corning Inc.) of 1 mm thickness was placed directly thereon, thus fabricating a sample in which the scattering loss due to the surface roughness of the conductive film is eliminated. The transmittance and reflectance of these samples at 400 to 550 nm were measured with a spectrophotometer, and the absorbance was determined from the results. On the other hand, methylene iodide was applied on an undercoating thin film of a glass substrate not provided with a transparent conductive film, and a cover glass was placed directly thereon to fabricate a reference sample, and the absorbance of the reference sample was determined in the same manner as described above. The absorption coefficient of the transparent conductive film was determined by subtracting the absorbance of the reference sample from the absorbance of the sample and solving the equations including terms for multiple reflections.

Component Concentrations in the Transparent Conductive Film

The fluorine concentration and the chlorine concentration were calculated from the characteristic X-ray intensities of an electron microanalyzer.

Ratio Between the Number ofTin Atoms and the Number of Carbon Atoms (C/Sn) in the Transparent Conductive Film

The ratio of the number of carbon atoms to the number of tin atoms was determined by X-ray photoelectron spectrometry from the atom peak area of Sn3d5/2 and C1s.

In the following working examples and comparative examples, an undercoating film whose principal component is silica and a transparent conductive film whose principal component is tin oxide doped with fluorine were deposited on a glass ribbon of 5 mm thickness by online CVD using the apparatus shown in FIG. 1. Inside the shaping bath, a non-oxidizing gas mixture of 98 vol % nitrogen and 2 vol % hydrogen was constantly supplied at a pressure that was slightly higher than the external pressure. Moreover, a soda-lime-silica glass, which contains a large quantity of alkali components, was used for the glass ribbon. After the glass ribbon was hardened in the annealing furnace, it was cut to a predetermined size using a cutting device (not shown in the drawings) arranged further downstream. The following is a more detailed explanation of the film deposition conditions.

### Working Example 1

A gas mixture made of monosilane, ethylene, oxygen and nitrogen was supplied from the coater positioned furthest to the upstream side, and an undercoating film with about 30 nm film thickness whose principal component is silica was deposited on the glass ribbon. Subsequently, a gas mixture obtained by mixing a nitrogen carrier gas such that it contains 1.9 mol % dimethyltin dichloride (vapor), 36 mol % oxygen, 33 mol % water vapor, 5 mol % helium and 0.5 mol % hydrogen fluoride was supplied from a coater further downstream and a transparent conductive film of about 700 nm thickness whose principal component is tin oxide doped with fluorine was deposited at a film deposition speed of 5000 nm/min. The surface temperature of the glass ribbon just before depositing the transparent conductive film was about 650° C.

The film deposition conditions and the properties of this transparent conductive film are listed in Table 1 and Table 2.

### Working Example 2

The concentration of the dimethyltin dichloride, the film deposition speed and the surface temperature of the glass ribbon just before depositing the transparent conductive film in Working Example 1 were changed as shown in Table 1, but otherwise the undercoating film and the transparent

The film deposition conditions and the properties of this transparent conductive film are listed in Table 1 and Table 2.

### Working Example 3

Monobutyltin trichloride was used instead of the dimethyltin dichloride, and the film deposition speed and the surface temperature of the glass ribbon just before depositing the transparent conductive film in Working Example 1 were changed as shown in Table 1, but otherwise the undercoating film and the transparent conductive film were deposited in the same manner as in Working Example 1.

The film deposition conditions and the properties of this transparent conductive film are listed in Table 1 and Table 2.

### Comparative Examples 1 to 3

The concentration of the dimethyltin dichloride, the film deposition speed and the surface temperature of the glass ribbon just before depositing the transparent conductive film in Working Example 1 were changed as shown in Table 1, but otherwise the undercoating film and the transparent conductive film were deposited in the same manner as in Working Example 1.

The film deposition conditions and the properties of these transparent conductive films are listed in Table 1 and Table 2.

TABLE 1
Film Deposition Conditions

| | | tin raw mat. | glass temp. | |
|---|---|---|---|---|
| | tin raw | concentr. | during film | film deposition |
| | material | (mol %) | deposi. (° C.) | speed (nm/min) |
| Working Ex. 1 | DMT | 1.9 | 650 | 5000 |
| Working Ex. 2 | DMT | 1.8 | 640 | 4500 |
| Working Ex. 3 | MBTC | 1.9 | 660 | 5500 |
| Comp. Ex. 1 | DMT | 2.7 | 650 | 6200 |
| Comp. Ex. 2 | DMT | 2.5 | 640 | 5800 |
| Comp. Ex. 3 | DMT | 3.7 | 660 | 7500 |

DMT = dimthyltin dichloride;
MBTC = monobutyltin trichloride

TABLE 2
Properties of Transparent Conductive Film

| | fluorine | chlorine | C/Sn (ratio | absorption coeff. | | sheet |
|---|---|---|---|---|---|---|
| | concentr. | concentr. | of atom | (10³ cm⁻¹) | | resistance |
| | (wt %) | (wt %) | numbers) | 400 nm | 500 nm | (Ω/□) |
| Working Ex. 1 | 0.07 | 0.05 | 0.002 | 0.38 | 0.35 | 9.5 |
| Working Ex. 2 | 0.07 | 0.05 | 0.002 | 0.37 | 0.35 | 9.5 |
| Working Ex. 3 | 0.07 | 0.06 | 0.003 | 0.39 | 0.36 | 9.4 |
| Comp. Ex. 1 | 0.07 | 0.05 | 0.006 | 0.64 | 0.54 | 8.8 |
| Comp. Ex. 2 | 0.06 | 0.04 | 0.005 | 0.61 | 0.50 | 13.8 |
| Comp. Ex. 3 | 0.06 | 0.05 | 0.008 | 0.87 | 0.61 | 12.3 |

Looking at the Working Examples 1 to 3 and the Comparative Examples 1 to 3 in general, it can be seen that the film deposition speed, the ratio of the number of carbon atoms to the number of tin atoms in the transparent conductive film and the absorption coefficient at 400 nm wavelength and at 500 nm wavelength increase in correspondence with the organic tin compound concentration. Moreover, it can be seen that in the Comparative Examples 1 to 3, in which the concentration of the organic tin compound exceeds 2 mol %, the absorption coefficient is about the same as in conventional transparent conductive films.

Furthermore, layered thin-film photoelectric conversion devices were fabricated in which amorphous silicon photoelectric conversion units and crystalline silicon photoelectric conversion units were formed in that order on the glass/transparent conductive film formed in Working Examples 1 and 2 and in Comparative Examples 1 and 2.

The following is an explanation of the procedure of this fabrication method. First, using a plasma CVD apparatus, an amorphous silicon photoelectric conversion unit with a total thickness of 300 nm made of an amorphous p-type silicon carbide layer, an undoped amorphous i-type silicon photoelectric conversion layer and an n-type silicon layer was formed in that order on the above-described transparent conductive film. Then, a p-type crystalline silicon layer, an i-type silicon photoelectric conversion layer and an n-type silicon layer were deposited in that order, thus forming a crystalline silicon photoelectric conversion unit with a total thickness of 1.5 μm. Furthermore, a zinc oxide film of 90 nm thickness and an Ag film of 200 nm thickness were formed by sputtering as the rear-side metal electrode. Next, a layered thin-film photoelectric conversion device of 1 by 1 cm square was fabricated by eliminating the photoelectric unit and the metal rear-side electrode along the periphery with a YAG SHG pulsed laser, but leaving the transparent conductive film. Table 3 lists the resulting solar cell properties at a measurement temperature of 25° C. under artificial sunlight of AM 1.5 and 1 kW/m².

TABLE 3
Solar Cell Properties

| | open-circuit | short-circuit | | conversion |
|---|---|---|---|---|
| | voltage | current density | fill factor | efficiency |
| Working Ex. 1 | 1.00 | 1.03 | 1.00 | 1.03 |
| Working Ex. 1 | 1.00 | 1.03 | 1.00 | 1.03 |
| Comp. Ex. 1 | 1.00 | 1.00 | 1.00 | 1.00 |
| Comp. Ex. 2 | 1.00 | 1.00 | 0.98 | 0.98 |

Note that the parameters of the solar cell properties have been normalized using the values in Comparative Example 1. Moreover, with the above-described film thickness configuration, the short-circuit current of the photoelectric devices is limited by the short-circuit current that is obtained on the side of the amorphous silicon photoelectric conversion unit.

Looking at the properties of the photoelectric conversion devices, the short-circuit current density on the amorphous photoelectric conversion unit side of the working examples is 3% higher than that of the comparative examples, which reflects that the working examples have an absorption coefficient at 400 to 500 nm wavelength, which is the optical absorption region of the amorphous photoelectric conversion units, that is only about half that of the comparative examples.

Due to the above configuration, the present invention displays the following effects.

With the method for depositing a transparent conductive film according to the present invention, the film deposition speed can be kept down by using an organic tin compound as the tin raw material in online CVD and controlling its concentration. The transparent conductive film formed as the result has no giant crystal grains, has a low carbon content photoelectric conversion devices. Furthermore, a photoelectric conversion device utilizing a glass substrate provided with this transparent conductive film has no defects, such as short circuits, and can display a high photoelectric conversion efficiency.

1. A method for forming a transparent conductive film whose principal component is tin oxide by CVD on a glass ribbon, comprising:
depositing the transparent conductive film at a film deposition speed of 3000 to 7000 nm/min using a raw material gas including 0.5 to 2.0 mol % of an organic tin compound.

2. The method for forming a transparent conductive film according to claim 1, wherein the organic tin compound comprises at least 70 mol % of at least one selected from dimethyltin dichloride and monobutyltin trichloride.

3. The method for forming a transparent conductive film according to claim 1, wherein the raw material gas comprises at least 10 mol % oxidation raw material.

4. A transparent conductive film formed by the method according to claim 1,
wherein an absorption coefficient at 400 to 550 nm wavelength is not greater than 0.40×10³ cm⁻¹, and a ratio of the number of carbon atoms to the number of tin atoms is smaller than 4×10⁻³.

5. A glass substrate on whose surface is formed a transparent conductive film according to claim 1.

6. The glass substrate according to claim 5, wherein an undercoating film is formed between the glass substrate and the transparent conductive film.

7. A photoelectric conversion device comprising a glass substrate according to claim 5.
